(19) United States
(12) Patent Application Publication
(10) Pub. No.: US 2008/0066660 A1
(43) Pub. Date: Mar. 20, 2008

(54) Latching mechanism

(75) Inventors: Feng Xiao, Kunshan (CN); Xiang-Qi Yang, Kunshan (CN)

Correspondence Address: WEI TE CHUNG;FOXCONN INTERNATIONAL, INC., 1650 MEMOREX DRIVE, SANTA CLARA, CA, 95050, US

(73) Assignee: HON HAI PRECISION IND. CO., LTD.

(21) Appl. No.: 11/901,328

(22) Filed: Sep. 17, 2007

(30) Foreign Application Priority Data
Sep. 15, 2006 (CN) 200620077327.X

(51) Int. Cl. H05K 1/14

(52) U.S. Cl. 108/91

(57) ABSTRACT

A latching mechanism (1) for use with a card edge connector to hold a card on a printed circuit board, the latching mechanism (1) includes a latching member (2), a supporting member (3) detachably fixed to the latching member (2) and adapted to be fastened said printed circuit board, of which has a linking portion (30, 34) for jointing the latching member (2) on the supporting member (3), a mounting portion (32) and a supporting portion (31, 33) connecting the linking portion (30, 34) and the mounting portion (32).

### BACKGROUND

1. Field of the Invention

The invention relates to an electrical assembly, and particularly to a printed circuit board assembly having an card electrically and mechanically connected to a mother board via a card edge connector and a latching mechanism in a parallel manner.

2. The Related Art

U.S. Pat. No. 7,021,953 discloses a latching mechanism for use with a card edge connector, wherein the latching mechanism defines a latching portion at a distal end of a spring arm, a support portion and a positioning post, which extends upwardly from the support portion. The latching mechanism is made from a single metal piece in forming which results in complicated structure and the uncontrollable dimension and position precision. Understandably, this design has difficulties in manufacturing. On the other hand, the latching mechanism is fixed in shape and height in every application, which is difficult to match some different card edge connectors in height.

Therefore, it is desired to have an improved latching mechanism for use with the card edge connector.

### SUMMARY OF THE INVENTION

Accordingly, an object of the present invention is to provide a latching mechanism which is adapted to match some card edge connectors different in heights.

To achieve the above-mentioned object, a latching mechanism is provided for use with a card edge connector to hold a card on a printed circuit board. The latching mechanism comprises a latching member, a supporting member detachably fixed to the latching member and adapted to be fastened to said printed circuit board, the supporting member having a linking portion for jointing the latching member on the supporting member, a mounting portion and a supporting portion connecting the linking portion and the mounting portion.

Other objects, advantages and novel features of the present invention will become more apparent from the following detailed description of the present embodiment when taken in conjunction with the accompanying drawings.

### BRIEF DESCRIPTION OF THE DRAWINGS

FIG. 1 is a perspective view of the latching mechanism of an exemplary embodiment of the present invention.

FIG. 2 is an enlarged perspective view of the latching member of the latching mechanism.

FIG. 3 is an enlarged perspective view of the supporting member of the latching mechanism.

FIG. 4 is an enlarged perspective view of the latching member of the latching mechanism taken from a different perspective of FIG. 3.

FIG. 5 is an enlarged perspective view of the latching member of the latching mechanism taken from a different perspective of FIG. 2.

### DETAILED DESCRIPTION OF THE PREFERRED EMBODIMENT

References will now be made to the drawing figures to describe the preferred embodiment of the present invention in detail.

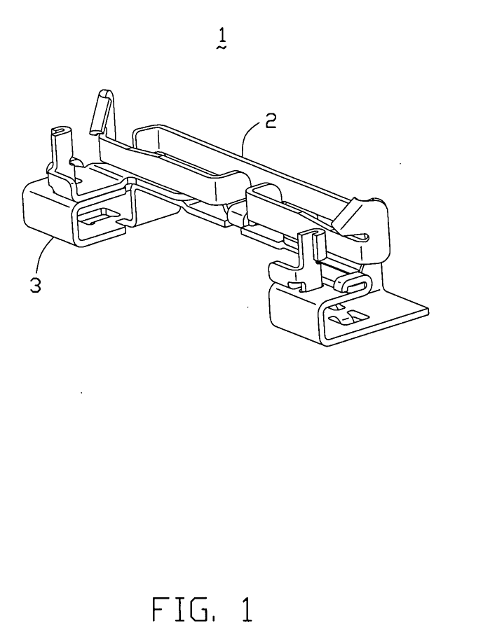

It will be noted here that for a better understanding, most of like components are designated by like reference numerals throughout the various figures in the embodiments. Referring to FIG. 1, a latching mechanism 1 and a card edge connector (not shown) are commonly mounted to a printed circuit board (not shown) for holding a card (not shown) on the printed circuit board. One end of the card is received in the card edge connector, the other end of the card defining two locating holes is latched by the latching mechanism 1.

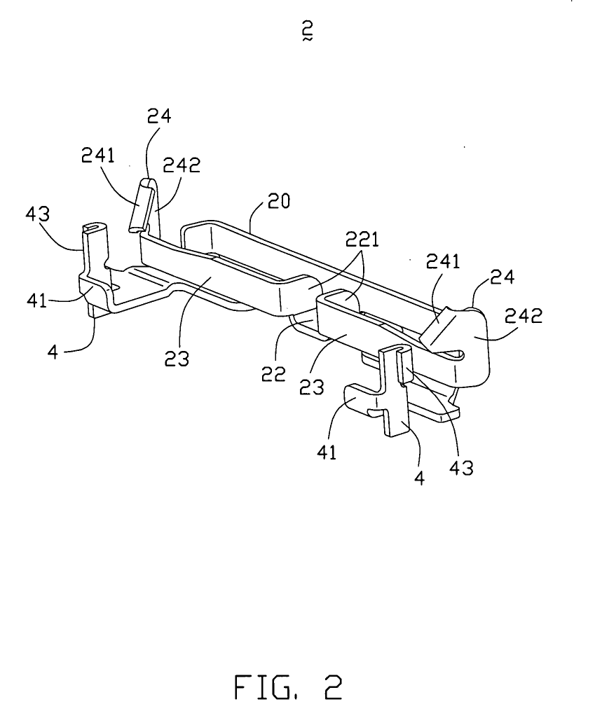

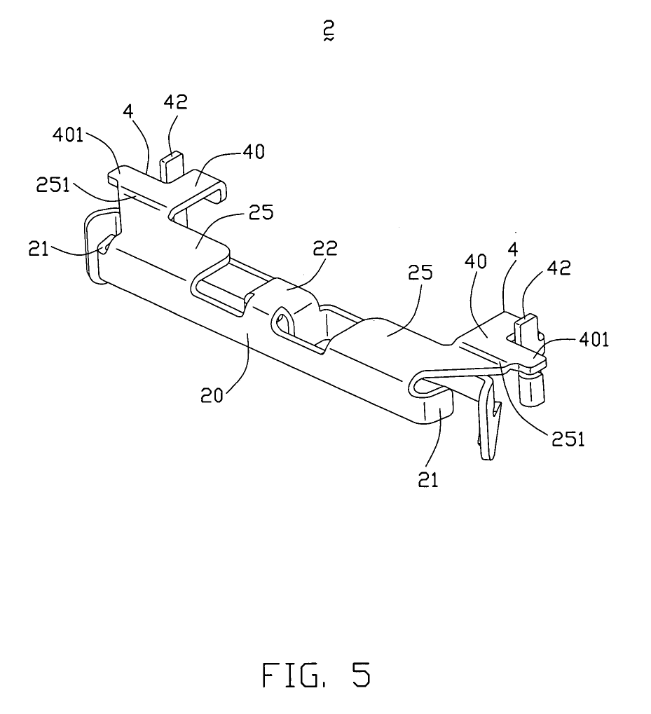

Referring to FIGS. 1-2, 5, the latching mechanism 1 includes a latching member 2 and a supporting member 3. The latching member 2 made from a single metal piece in forming has a connecting portion 20 extending laterally, wherein the connecting portion 20 defines a pair of restricting portions 21 bending frontwardly from a pair of lateral ends of the connecting portion 20. The connecting portion 20 has a connecting end 22 extending frontwardly from the middle of the connecting portion 20, and the connecting end 22 has a pair of sidwalls 221 extending upwardly from the pair of lateral ends of connecting end 22. The pair of sidewalls 221 extend and form a spring arm 23 separately in opposite direction which is parallel with the connecting portion 20. The spring arm 23 has a hook 24 which is bent frontwardly from the spring arm 23, and the hook 24 includes a slant guiding face 241 and a middle portion 242 connecting the hook 24 to the spring arm 23. The connecting portion 20 has a pair of extending portions 25 extending frontwardly between the connecting end 22 and the restricting portions 21, and the extending portion 25 has a slant portion 251. The slant portion 251 connects a fixing portion 4 to the extending portion 25, wherein the fixing portion 4 has a mounting face 40 and a protrusion 401. The fixing portion 4 extends upwardly and defines a resting portion 41, a positioning post 43 extending upwardly from the resting portion 41, and a fixing post 42 extending downwardly from the resting portion 41 and protruding beyond the mounting face 40.

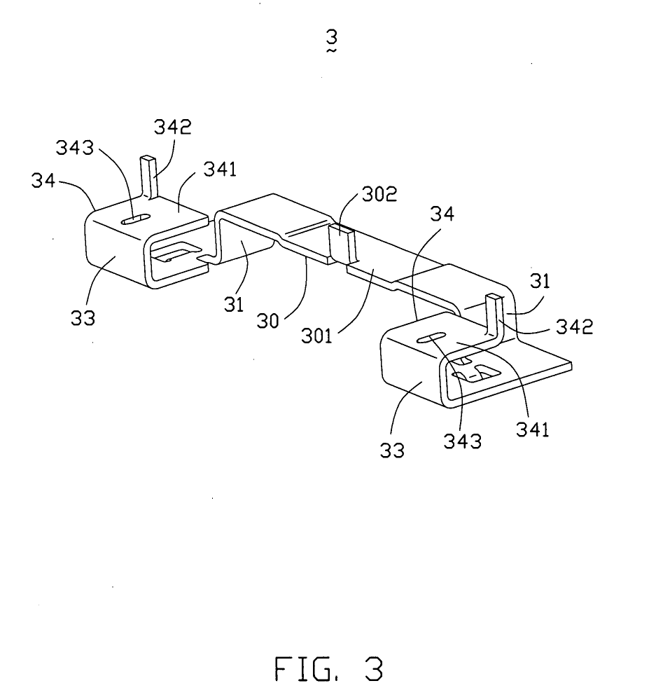

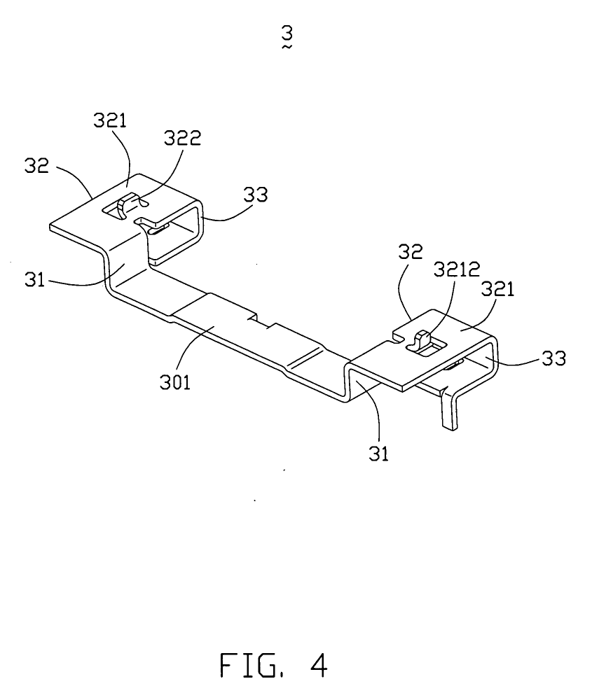

Referring to FIGS. 3-4, the supporting member 3 made from a single metal piece in forming has a first linking portion 30 which includes a first body 301 and a first joint 302. The first body 301 extends downwardly from two opposite ends of the first body 301 and forms a pair of first supporting portions 31. The downward end of the first supporting portion 31 is bent to form a mounting portion 32 which includes a plane-like mounting member 321 and a positioning member 322. A second supporting portion 33 extending upwardly from the mounting member 321 has a second linking portion 34 which includes a second body 341 and a second joint 342, and the second body 341 defines a inserting hole 343 opening toward the upside of second body 341 for receiving the fixing post 42.

Referring to FIG. 1, the latching member 2 is fastened to the supporting member 3 by means of the first joint 302 of the first linking portion 30 jointing to the connecting end 22 and the second joint 342 jointing to the protrusion 401 of the fixing portion 4. Under this condition, the extending portions 25 of the latching member 2 rest on the first body 301 of the supporting member 3, the mounting faces 40 of the fixing portions 4 rest on the second bodies 341 of the supporting member 3, and the fixing posts 42 are respectively received in the inserting holes 343.

The latching mechanism 1 is fastened to the printed circuit board by means of the mounting member 321 of the supporting member 3 mounting to the printed circuit board. During assembling, one end of the card is inserted initially into the card edge connector, and an opposite end of the card is successively downwardly moved toward the passing the guiding face 241 of the hook 24. At the same time, the card is correctly positioned relative to the printed circuit board via the positioning posts 43 extending through the locating holes of the card in a stable downward movement. When the opposite end of the card completely passes the hooks 24, the spring arms 23 resume the original position to have the hook 24 downwardly press the card. Under this condition, the card can not further upwardly moved because of the hook 24, and further horizontally moved by means of the positioning posts 43 extending through the locating holes of the card. During disassembling, the hooks 24 are moved rearwardly to have the corresponding spring arms 23 moved rearwardly associatively, and the card is disengaged from the hook 24. The restricting portions 21 prevent the spring arms 23 from bending too much.

Understandably, the supporting member 3 could be manufactured in different height with the first and second supporting portion 31 being corresponding height. So the latching mechanism 1 would match a different height card connector, at the same time, the latching member 2 is a standard structure, and the supporting member 3 is a corresponding height. In some state, the first linking portion 30, the first supporting portions 31 and the fixing portions 32 server as a supporting member, or, the second linking portion 34, the second supporting portions 33 and the fixing portions 32 also server as a supporting member. In some other state, the mounting faces 40 of the latching member 2 are welded to the second bodies 341 of the supporting member 3 for jointing the latching member 2 and the supporting member 3 together stably. On the other hand, the latching member 2 may server as a latching mechanism for matching a card edge connector to hold the card on the printed circuit board 2. Under this condition, the fixing portion 4 server as a mounting portion for mounting to the printed circuit board.

While the present invention has been described with reference to specific embodiments, the description is illustrative of the invention and is not to be construed as limiting the invention. Various modifications to the present invention can be made to the preferred embodiments by those skilled in the art without departing from the true spirit and scope of the invention as defined by the appended claims. Therefore, person of ordinary skill in this field are to understand that all such equivalent structures are to be included within the scope of the following claims.

We claim:

1. A latching mechanism for use with an electrical connector to hold a card on a printed circuit board, the latching mechanism comprising:
a latching member;
a supporting member detachably fixed to the latching member and adapted to be fastened to said printed circuit board, the supporting member having a linking portion for jointing the latching member on the supporting member, a mounting portion and a supporting portion connecting the linking portion and the mounting portion.

2. The latching mechanism as described in claim 1, wherein the linking portion is a first linking portion having a first body, the supporting portion is a first supporting portion, the mounting portion has a mounting member, the first supporting portion extends upwardly from one edge of the mounting member, and the first linking portion extends from the upward end of the first supporting portion in a perpendicular direction.

3. The latching mechanism as described in claim 2, wherein said first linking portion has a first joint extending from the first body.

4. The latching mechanism as described in claim 2, wherein a second supporting portion extends upwardly from another edge of said mounting member of the mounting portion, a second linking portion having a second body extends from the upward end of the second supporting portion in a perpendicular direction.

5. The latching mechanism as described in claim 2, wherein the first linking portion is elongated, two opposite elongated ends of the first linking portion connect a said first supporting portion respectively.

6. The latching mechanism as described in claim 2, wherein said mounting portion has a positioning member extending downwardly from the mounting member.

7. The latching mechanism as described in claim 3, wherein said latching member has a connecting end coupling with the first joint and a pair of spring arms extending from the connecting end in an opposite direction, each free end of the pair of spring arms has a hook.

8. The latching mechanism as described in claim 4, wherein said second linking portion has a second joint extending from the second body and a inserting hole defining in the second body.

9. The latching mechanism as described in claim 5, wherein said mounting portion has a positioning member extending downwardly from the mounting member.

10. The latching mechanism as described in claim 7, wherein said latching member has a connecting portion extending from the connecting end, the connecting portion is parallel with the spring arms and has two restricting portions extending toward the spring arms at the opposite free ends of the connecting portion.

11. The latching mechanism as described in claim 5, wherein a second supporting portion extends upwardly from another edge of said mounting member of the mounting portion, a second linking portion having a second body extends from the upward end of the second supporting portion in a perpendicular direction.

12. The latching mechanism as described in claim 11, wherein said second linking portion has a second joint extending from the second body and a inserting hole defining in the second body.

13. The latching mechanism as described in claim 5, wherein said first linking portion has a first joint extending from the first body.

14. The latching mechanism as described in claim 13, wherein said latching member has a connecting end matching with the first joint and a pair of spring arms extending from the connecting end in an opposite direction, each free end of the pair of spring arms has a hook.

15. The latching mechanism as described in claim 10, wherein said connecting portion extends and forms a fixing portion having a mounting face, a resting portion extending upwardly from the mounting face, a positioning post extending upwardly from the resting portion and a fixing post extending downwardly from the resting portion.

16. A latching mechanism for use with an electrical connector to hold a card on a printed circuit board, the latching mechanism comprising:
a latching member having a fixing post extending downwardly from the latching member;
a supporting member detachably fixed to the latching member and adapted to be fastened to said printed circuit board, the supporting member having a linking portion for jointing the latching member on the supporting member, a mounting portion, a supporting portion connecting the linking portion and the mounting portion, and an inserting hole defining in the supporting member for receiving the fixing post.

17. The latching mechanism as described in claim 17, wherein said linking portion has a body and a joint extending from the body, the inserting hole is defined in the body and open toward the upside of the body.

18. A metallic latching mechanism comprising:
a front region and a rear region in a front-to-back direction;
a latch member made by one piece metal and including a pair of deflectable arms each horizontally extending in a transverse direction, perpendicular to said front-to-back direction, with a downward hook at a distal end thereof;
a supporting member made by another piece metal and including an upward supporting face to supportably fasten said latch member thereto at least at two opposite positions each closer to the hook.

19. The latching mechanism as claimed in claim 18, wherein the upward support face spans in a lying U-like configuration wherein two arms of said U-like configuration are located in the front region while a bight of the U-like configuration bridging said two arms is located in the rear region.

20. The latching mechanism as claimed in claim 18, wherein said latch member further is unitarily equipped with a pair of positioning posts located in the front region
